(19) United States
(12) Patent Application Publication
(10) Pub. No.: US 2015/0093886 A1
(43) Pub. Date: Apr. 2, 2015

(54) PLASMA PROCESSING METHOD AND PLASMA PROCESSING APPARATUS

(71) Applicant: TOKYO ELECTRON LIMITED, Tokyo (JP)

(72) Inventors: Minoru Honda, Yamanashi (JP); Toshio Nakanishi, Yamanashi (JP); Daisuke Katayama, Yamanashi (JP)

(73) Assignee: TOKYO ELECTRON LIMITED, Tokyo (JP)

(21) Appl. No.: 14/396,589

(22) PCT Filed: Apr. 23, 2013
(86) PCT No.: PCT/JP2013/061927

§ 371 Date: Oct. 23, 2014

(30) Foreign Application Priority Data
Apr. 24, 2012 (JP) 2012-098769

(51) Int. Cl. H01L 29/66; C30B 29/06; C30B 28/14; H01L 21/02; H01L 21/67

(52) U.S. Cl. CPC H01L 29/66121; H01L 21/02532; H01L 21/67207; H01L 21/02595; H01L 21/02576; H01L 21/02579; C30B 28/14; C30B 29/06
USPC 438/491; 118/723 AN

(57) ABSTRACT

A plasma processing method of one embodiment of the present invention is disclosed for growing a polycrystalline silicon layer on a base material to be processed. The plasma processing method includes: (a) a step for preparing, in a processing container, the base material to be processed; and (b) a step for growing the polycrystalline silicon layer on the base material by introducing microwaves for plasma excitation into the processing container, and introducing a silicon-containing raw material gas into the processing container.

### TECHNICAL FIELD

Several aspects and exemplary embodiments of the present disclosure relate to a plasma processing method and a plasma processing apparatus, and more particularly, to a plasma processing method which grows a polycrystalline silicon layer on a substrate to be processed (“processing target substrate”) and a plasma processing apparatus which is used to carry out the method.

### BACKGROUND ART

As one of semiconductor devices, a pin diode having a structure in which a non-doped (i-type) semiconductor layer having a high electrical resistance is sandwiched between a p-type semiconductor layer and an n-type semiconductor layer is known. The pin diode is formed by sequentially growing a p-type silicon layer doped with boron (B), an i-type polycrystalline silicon (polysilicon) layer, and an n-type silicon layer doped with phosphate (P), on, for example, a substrate.

A plasma chemical vapor deposition (CVD) method is known as a method of growing the p-type silicon layer, the i-type polycrystalline silicon layer, and the n-type silicon layer. The plasma CVD method generates plasma of a raw material gas containing a semiconductor raw material to react the plasma of the raw material gas on a growth substrate, thereby growing the semiconductor layer. Further, a thermal CVD method is also known as another method of growing the semiconductor layers. The thermal CVD method heats the raw material gas to thermally decompose gas molecules and reacts the thermally decomposed gas molecules on the growth substrate to grow the semiconductor layer (for example, see Non-Patent Document 1).

### PRIOR ART DOCUMENT

### Non-Patent Document

Non-Patent Document 1: Takashi Hirao et al., “New Trends of Thin-Film Technology”, Kogyo-Chosakai Publishing Co., Ltd., 1997, pp 95-100

### SUMMARY OF INVENTION

### Technical Problem

A dopant is diffused from the p-type silicon layer or the n-type silicon layer onto the i-type silicon layer, which is considered as a factor of degrading an electric property of a pin diode. The diffusion of the dopant becomes prominent as the process is performed at a higher temperature. The inventors of the present application found that it is effective to grow crystals at a low temperature and make the crystals fine, that is, to grow a polycrystalline silicon having a small crystal size at a low temperature in order to suppress the diffusion of the dopant.

In a method of growing a semiconductor layer by a plasma CVD method which is carried out in a conventional plasma CVD apparatus, such as a parallel plate type plasma CVD apparatus, plasma of a raw material gas has a high electron temperature and thus ion energy is high. Therefore, a range of a condition of growing the polycrystalline silicon layer becomes narrower.

Further, in a method of growing a semiconductor layer by a thermal CVD method, a temperature of a growth substrate is raised to 700° C. or higher in order to grow the polycrystalline silicon layer. When crystals are grown at the high temperature, a dopant of the p-type silicon layer or the n-type silicon layer may be diffused into the i-type polycrystalline silicon layer. Further, when crystals are grown at the high temperature, sizes of the silicon crystals which constitute the polycrystalline silicon layer become large.

Therefore, in the technical field, a method for growing a polycrystalline silicon layer having a small crystal size at a low temperature and an apparatus which is used to carry out the method are required.

### Solution to Problem

An aspect of the present disclosure provides a plasma processing method for growing a polycrystalline silicon layer on a substrate to be processed (“processing target substrate”). The method includes preparing a processing target substrate in a processing container; and growing the polycrystalline silicon layer on the processing target substrate by introducing microwaves for plasma excitation into the processing container and a silicon-containing raw material gas into the processing container.

In the plasma processing method, the plasma is excited by microwaves so that an electron temperature in the plasma is lower than an electron temperature of plasma which is generated by, for example, the parallel plate-type plasma processing apparatus, for example, in a range of 1 to 2 eV. In this method, film formation is performed by activating silicon contained in the raw material gas by the plasma. Thus, the polycrystalline silicon layer may be grown while reducing growth inhibition due to high ion energy. Further, in this method, the polycrystalline silicon layer may be grown at the low temperature so that a polycrystalline silicon layer with a fine crystal size may be grown. When the crystal size of the polycrystalline silicon layer is made to be fine, a grain boundary becomes a mesh type. Diffusion of the dopant may be suppressed in the polycrystalline silicon layer having such a mesh type complicated grain boundary.

In an exemplary embodiment, the growing of the polycrystalline silicon layer includes: growing a first conductive type polycrystalline silicon layer on the processing target substrate by introducing the raw material gas and a first gas containing a first dopant material into the processing container; growing an i-type polycrystalline silicon layer on the first conductive type polycrystalline silicon layer by introducing the raw material gas into the processing container; and growing a second conductive type polycrystalline silicon layer on the i-type polycrystalline silicon layer by introducing the raw material gas and a second gas containing a second dopant material into the processing container. According to the exemplary embodiment, plasma having a low electron temperature is excited so that the polycrystalline silicon layer may be grown in a state where dopant atoms are incorporated in a crystal structure of the polycrystalline silicon. Therefore, a first conductive type polycrystalline silicon layer and a second conductive type polycrystalline silicon layer which are activated may be grown.

In an exemplary embodiment, in the growing of the i-type polycrystalline silicon layer, a dilution gas containing hydrogen is introduced into the processing container. According to this exemplary embodiment, dilution gas is introduced so that a crystallization rate of the i-type polycrystalline silicon layer may be improved.

In an exemplary embodiment, in the growing of the i-type polycrystalline silicon layer, a high frequency bias power is applied to a mounting stage on which the processing target substrate is placed, the mounting stage constituting an electrode. According to the exemplary embodiment, a high frequency bias power is controlled to control ion energy of ions which are drawn into a processing target substrate so that a crystal size of the i-type polycrystalline silicon layer may be controlled.

In an exemplary embodiment, the high frequency bias power ranges from 100 W to 500 W. According to the exemplary embodiment, a crystallization rate of the i-type polycrystalline silicon layer may be further increased and a crystal size of the i-type polycrystalline silicon layer may be further reduced.

In an exemplary embodiment, in the growing of the polycrystalline silicon layer, a pressure within the processing container is set to be 12 Pa or less. According to the exemplary embodiment, a crystallization rate of the i-type polycrystalline silicon layer may be further increased.

Another aspect of the present disclosure provides a plasma processing apparatus, including: a processing container configured to accommodate a processing target substrate therein; a microwave generator configured to generate microwaves; an antenna connected to the microwave generator to radiate microwaves for plasma excitation into the processing container; and a gas introducing unit configured to introduce a silicon-containing raw material gas into the processing container.

In the plasma processing apparatus, the plasma is excited by microwaves so that an electron temperature (for example, 1 to 2 eV) in the plasma is lower than an electron temperature of plasma which is generated by the parallel plate-type plasma processing apparatus. In the present apparatus, film formation is performed by activating silicon contained in the raw material gas by the plasma. Thus, the polycrystalline silicon layer may be grown while reducing growth inhibition due to high ion energy. Further, in the present apparatus, the polycrystalline silicon layer is grown at the low temperature so that a polycrystalline silicon layer having a reduced crystal size may be grown. When the crystal size of the polycrystalline silicon layer is reduced, a grain boundary becomes a mesh type. Diffusion of the dopant may be suppressed in the polycrystalline silicon layer having such a mesh type complicated grain boundary.

In an exemplary embodiment, the plasma processing apparatus may further include a control unit configured to control the gas introducing unit and the microwave generator. The gas introducing unit may introduce a first gas containing a first dopant material and a second gas containing a second dopant material into the processing container. The control unit may cause the gas introducing unit to introduce the raw material gas and the first gas into the processing container to grow a first conductive type polycrystalline silicon layer on the processing target substrate, to introduce the raw material gas into the processing container to grow an i-type polycrystalline silicon layer on the first conductive type polycrystalline silicon layer, and to introduce the raw material gas and the second gas into the processing container to grow a second conductive type polycrystalline silicon layer on the i-type polycrystalline silicon layer. According to the embodiment, plasma having a low electron temperature is excited so that the polycrystalline silicon layer may be grown in a state where dopant atoms are incorporated in a crystal structure of the polycrystalline silicon. Therefore, a first conductive type polycrystalline silicon layer and a second conductive type polycrystalline silicon layer which are activated may be grown.

In an exemplary embodiment, the gas introducing unit may further introduce a dilution gas containing hydrogen into the processing container. The control unit causes the gas introducing unit to introduce the dilution gas into the processing container when the i-type polycrystalline silicon layer is grown. According to this embodiment, dilution gas is introduced so that a crystallization rate of the i-type polycrystalline silicon layer may be improved.

In an exemplary embodiment, the plasma processing apparatus further includes: a mounting stage on which the processing target substrate is placed, the mounting stage being provided in the processing container and constituting an electrode; and a high frequency power supply connected to the mounting stage and configured to generate a high frequency bias power to be applied to the electrode. According to the embodiment, a high frequency bias power is controlled to control ion energy of ions which are drawn into a processing target substrate so that a crystal size of the i-type polycrystalline silicon layer may be controlled.

In an exemplary embodiment, when the i-type polycrystalline silicon layer is grown, the control unit causes the high frequency power supply to generate a high frequency bias power ranging from 100 W to 500 W. According to the embodiment, a crystallization rate of the i-type polycrystalline silicon layer may be further increased and a crystal size of the i-type polycrystalline silicon layer may be further reduced.

In an exemplary embodiment of the present disclosure, the plasma processing apparatus may further include a pressure adjusting unit configured to adjust a pressure within the processing container. The control unit causes the pressure adjusting unit to set the pressure within the processing container to be 12 Pa or less. According to the exemplary embodiment, a crystallization rate of the i-type polycrystalline silicon layer may be further increased.

### Advantageous Effects of Invention

As described above, the present disclosure provides a method of growing a polycrystalline silicon layer having a small crystal size at a low temperature and an apparatus which is used to carry out the method.

### BRIEF DESCRIPTION OF DRAWINGS

FIG. 1 is a view schematically illustrating a plasma processing apparatus according to an exemplary embodiment.

FIG. 2 is a plan view of a slot plate according to an exemplary embodiment as seen from an axis X direction.

FIG. 3 is a flow chart illustrating a plasma processing method according to an exemplary embodiment.

FIG. 4 is a view schematically illustrating a principle of forming a film in a plasma processing method according to an exemplary embodiment.

FIG. 5 is a timing chart illustrating respective processes of a plasma processing method according to an exemplary embodiment.

FIG. 6 is a graph illustrating a relationship between a high frequency bias power and a crystal size of an i-type semiconductor layer and a relationship between a high frequency bias power and a crystallization rate of the i-type semiconductor layer.

FIG. 7 is a graph illustrating a relationship between a high frequency bias power and a crystallization rate of an i-type semiconductor layer.

FIG. 8 is a graph illustrating a relationship between a pressure in a processing container and a crystallization rate of an i-type semiconductor layer.

FIG. 9 is a graph illustrating a relationship between a microwave output power and a resistivity of a p-type semiconductor layer, a relationship between a temperature of a stage and a resistivity of the p-type semiconductor layer, and a relationship between a pressure in a processing container and a resistivity of the p-type semiconductor layer.

FIG. 10 is a graph illustrating a result of confirming that diffusion of a dopant is suppressed on an i-type polycrystalline silicon layer.

### DESCRIPTION OF EMBODIMENTS

Hereinafter, several exemplary embodiments will be described in detail with reference to the drawings. In the meantime, the same or corresponding part is denoted by the same reference numeral in the drawings.

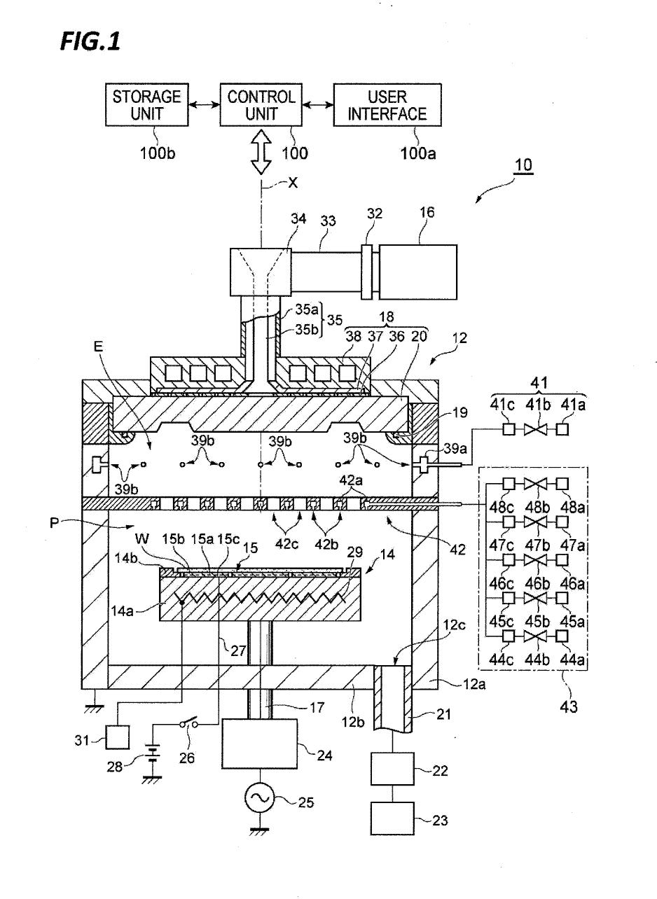

FIG. 1 is a view schematically illustrating a plasma processing apparatus according to an exemplary embodiment. A plasma processing apparatus 10 illustrated in FIG. 1 is a plasma processing apparatus which excites the plasma by microwaves and includes a processing container 12, a stage 14, a microwave generator 16, and an antenna 18.

The processing container 12 defines a plasma generating space E in which the plasma is generated and a processing space P in which the plasma processing is performed on a processing target substrate W, below the plasma generating space E. The processing container 12 may include a side wall 12a and a bottom portion 12b. The side wall 12a has a substantially cylindrical shape which extends in an axis X direction (that is, an extending direction of the axis X). An upper end of the side wall 12a is opened.

The opening of the upper end of the side wall 12a is closed by a dielectric window 20. An O-ring 19 may be interposed between the dielectric window 20 and the upper end of the side wall 12a. The processing container 12 is more securely sealed by the O ring 19.

The bottom portion 12b is formed at a lower end of the side wall 12a. An exhaust pipe 21 having an exhaust hole 12c is provided in the bottom portion 12b. The exhaust pipe 21 is connected to an exhausting device 23 through a pressure adjusting unit 22. The pressure adjusting unit 22 is controlled by a control unit to be described below and controls a flow rate of the exhausted gas to adjust a pressure in the processing container 12. The exhausting device 23 includes a vacuum pump such as, for example, a turbo molecular pump. A pressure of the processing space P in the processing container 12 may be reduced to a predetermined degree of vacuum by the exhausting device 23.

A stage 14 is provided in the processing container 12. The stage 14 is provided in a lower portion of the processing space P to face a shower plate 42 to be described below. The processing target substrate W is placed on the stage 14. In an exemplary embodiment, the stage 14 may include a table 14a, a focus ring 14b, and an electrostatic chuck 15. In the meantime, the stage 14 which includes the table 14a, the focus ring 14b, and the electrostatic chuck 15 constitutes a mounting stage according to an exemplary embodiment.

The table 14a is supported by a support 17 which extends upwardly from the bottom portion 12b of the processing container 12. The table 14a also serves as a high frequency electrode. An RF bias high frequency power supply 25 is electrically connected to the table 14a through a matching unit 24. The high frequency power supply 25 outputs a high frequency bias power of a predetermined frequency which is appropriate for controlling energy of ions which are drawn into the processing target substrate W, for example, 13.65 MHz at a predetermined power level. In an exemplary embodiment, the high frequency bias power may range from 100 W to 500 W. The matching unit 24 accommodates a matching device which matches impedance at the high frequency power supply 25 side with impedance at a load side mainly, such as, for example, an electrode, plasma, and the processing container 12. A self-bias generating blocking capacitor is included in the matching device.

The electrostatic chuck 15 which is a holding member configured to hold the processing target substrate W is provided on a top surface of the table 14a. The electrostatic chuck 15 holds the processing target substrate W by an electrostatic attractive force. The focus ring 14b which annularly surrounds the periphery of the processing target substrate W and the periphery of the electrostatic chuck 15 is provided outside the electrostatic chuck 15 in a radial direction.

The electrostatic chuck 15 includes an electrode 15a, an insulating layer 15b, and an insulating layer 15c. The electrode 15a is configured by a conductive layer and formed between the insulating layer 15b and the insulating layer 15c. A high voltage DC power supply 28 is electrically connected to the electrode 15a through a switch 26 and a coated wire 27. The electrostatic chuck 15 may hold the processing target substrate W by a coulomb force which is generated by a DC voltage applied from the DC power supply 28.

A heater 29 is provided in the table 14a. The heater 29 is connected to a heater power supply 31 and generates heat by a power supplied from the heater power supply 31 so as to heat the processing target substrate W.

The microwave generator 16 generates microwaves having, for example, a frequency of 2.45 GHz. In an exemplary embodiment, the plasma processing apparatus 10 may further include a tuner 32, a waveguide 33, a mode converter 34, and a coaxial waveguide 35.

The microwave generator 16 is connected to the waveguide 33 through the tuner 32. The waveguide 33 is, for example, a rectangular waveguide. The waveguide 33 is connected to the mode converter 34 and the mode converter 34 is connected to an upper end of the coaxial waveguide 35.

The coaxial waveguide 35 extends along an axis X. The coaxial waveguide 35 includes an outer conductor 35a and an inner conductor 35b. The outer conductor 35a has a substantially cylindrical shape which extends in the axis X direction. The inner conductor 35b is provided in the outer conductor 35a. The inner conductor 35b has a substantially cylindrical shape which extends along the axis X.

The microwaves generated by the microwave generator 16 are guided to the mode converter 34 through the tuner 32 and the waveguide 33. The mode converter 34 converts a mode of the microwaves and supplies the mode-converted microwaves to the coaxial waveguide 35. The microwaves from the coaxial waveguide 35 are supplied to the antenna 18.

The antenna 18 radiates microwaves for plasma excitation into the plasma generating space E based on the microwaves generated by the microwave generator 16. The antenna 18 may include the dielectric window 20, a slot plate 36, a dielectric plate 37, and a cooling jacket 38. The microwaves from the coaxial waveguide 35 are propagated to the dielectric plate 37 to be radiated into the plasma generating space E through the dielectric window 20 from slots of the slot plate 36.

The dielectric window 20 has substantially a disk shape and for example, is formed of quartz. The dielectric window 20 is provided just below the slot plate 36 in the axis X direction.

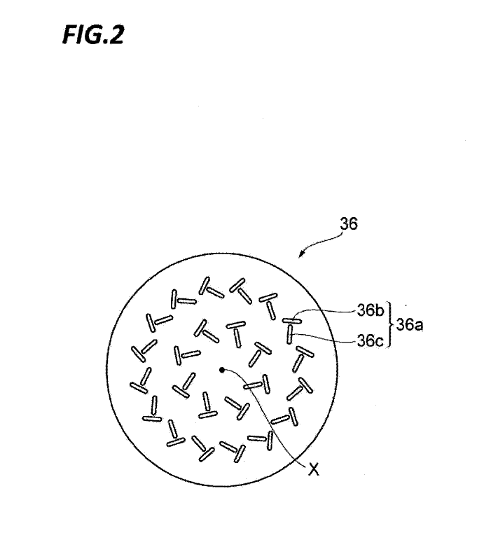

FIG. 2 is a plan view of the slot plate 36 according to an exemplary embodiment as seen from the axis X direction. As illustrated in FIG. 2, a plurality of slot pairs 36a is arranged in the slot plate 36 in a circumferential direction around the axis X. In an exemplary embodiment, the slot plate 36 may constitute a radial line slot antenna. The slot plate 36 is formed of a disk made of a conductive metal. The plurality of slot pairs 36a is formed on the slot plate 36. Each slot pair 36a includes a slot 36b and a slot 36c which extend in intersecting or perpendicular directions. The plurality of slot pairs 36a is disposed at predetermined intervals in a radial direction and also disposed at predetermined intervals in a circumferential direction.

As illustrated in FIG. 1, the dielectric plate 37 is provided between the slot plate 36 and a bottom surface of the cooling jacket 38. The dielectric plate 37 is made of, for, example, quartz and has substantially a disk shape. The surface of the cooling jacket 38 may be conductive. The cooling jacket 38 cools down the dielectric plate 37 and the slot plate 36. Therefore, a fluid channel for a coolant is formed in the cooling jacket 38. A lower end of the outer conductor 35a is electrically connected to the top surface of the cooling jacket 38. Further, a lower end of the inner conductor 35b is electrically connected to the slot plate 36 via a hole which is formed in centers of the cooling jacket 38 and the dielectric plate 37.

In an exemplary embodiment, a gas flow channel 39a and a plurality of injection holes 39b are formed in the side wall 12a of the processing container 12. The gas flow channel 39a extends annularly around the axis X and is connected to a gas supplying unit 41. The gas supplying unit 41 supplies a gas for generating plasma to the gas flow channel 39a. The gas for generating plasma which is supplied by the gas supplying unit 41 is, for example, Ar gas or H₂ gas. The gas supplying unit 41 may include a gas source 41a, a valve 41b, and a flow rate controller 41c. The gas source 41a is a gas source of the gas for generating plasma. The valve 41b switches supply and supply stop of the gas from the gas source 41a. The flow rate controller 41c is, for example, a mass flow controller and adjusts a flow rate of the gas from the gas source 41a. The plurality of injection holes 39b is connected to the gas flow channel 39a configured to receive the gas for generating plasma from the gas supplying unit 41. The plurality of injection holes 39b is arranged annularly around the axis X. The plurality of injection holes 39b injects the gas for generating plasma into the plasma generating space E and injects the gas toward the axis X.

In an exemplary embodiment, the plasma processing apparatus 10 may further include a shower plate 42. The shower plate 42 is interposed between the plasma generating space E and the processing space P and introduces a processing gas for forming a film into the processing space P. The shower plate 42 is formed in a lattice shape and a gas flow channel 42a is formed in the lattice. That is, the gas flow channel 42a which extends in a lattice shape is formed in the shower plate 42. The gas flow channel 42a of the shower plate 42 is connected to a gas supplying unit 43.

The gas supplying unit 43 supplies a processing gas for forming a film to the gas flow channel 42a. The gas supplying unit 43 includes a plurality of gas sources 44a to 48a, a plurality of valves 44b to 48b which is connected to the gas sources 44a to 48a, respectively, and a plurality of flow rate controllers 44c to 48c which is connected to the valves 44b to 48b, respectively.

The gas source 44a is a gas source for a silicon-containing raw material gas. The raw material gas is, for example, SiH₄ gas. The gas source 44a is connected to the gas flow channel 42a through the valve 44b and the flow rate controller 44c. The gas source 45a is a gas source for a first gas containing a first dopant material. The first gas may contain, for example, boron (B) as the first dopant material. The first gas is, for example, B₂H₆ gas. The gas source 45a is connected to the gas flow channel 42a through the valve 45b and the flow rate controller 45c. Further, the gas source 46a is a gas source for a second gas containing a second dopant material. The second gas may contain, for example, phosphate (P) as the second dopant material. The second gas is, for example, PH₃ gas. The gas source 46a is connected to the gas flow channel 42a through the valve 46b and the flow rate controller 46c. The gas source 47a is a gas source of dilution gas. The dilution gas is, for example, hydrogen (H₂) gas. The gas source 47a is connected to the gas flow channel 42a through the valve 47b and the flow rate controller 47c. The gas source 48a is a gas source of another dilution gas. The another dilution gas is, for example, argon (Ar) gas. The gas source 48a is connected to the gas flow channel 42a through the valve 48b and the flow rate controller 48c.

Further, a plurality of injection holes 42b which is connected to the gas flow channel 42a is formed on the shower plate 42. The plurality of injection holes 42b downwardly injects the processing gas which is supplied to the gas flow channel 42a to supply the processing gas into the processing space P. In the meantime, the shower plate 42 and the gas supplying unit 43 constitute a gas introducing unit according to an exemplary embodiment.

Further, the shower plate 42 formed in a lattice shape defines a plurality of holes 42c which communicates the plasma generating space E with the processing space P. A gas turned into a plasma state in the plasma generating space E is supplied to the processing space P through the plurality of holes 42c to activate the processing gas for forming a film in the processing space P.

In an exemplary embodiment, the plasma processing apparatus 10 may further include a control unit 100 which includes a programmable microprocessor (computer). The control unit 100 may control individual components of the plasma processing apparatus 10, for example, the high frequency power supply 25, the gas supplying units 41 and 43, and the pressure adjusting unit 22. Further, the plasma processing apparatus 10 may further include a user interface 100a which is connected to the control unit 100. The user interface 100a includes, for example, a keyboard through which an operator inputs a command to manage the plasma processing apparatus 10 or a display which visualizes and displays an operating condition of the plasma processing apparatus 10.

Further, a storage unit 100b is connected to the control unit 100. In the storage unit 100b, a control program which controls the control unit 100 to execute various processings which are performed in the plasma processing apparatus 10 or a program which causes the individual components of the plasma processing apparatus 10 to perform the processing in accordance with a processing condition, that is, processing recipes are stored. The processing recipes are stored in a storage medium in the storage unit 100b. The storage medium may be a hard disk or a semiconductor memory or may be a portable medium, such as a CD ROM, a DVD, or a flash memory. Further, the recipes may be appropriately transmitted from other devices, for example, through a dedicated line.

If necessary, an arbitrary processing recipe is retrieved from the storage unit 100b by, for example, the command from the user interface 100a to allow the control unit 100 to execute the processing recipe, so that a desired processing is performed in the plasma processing apparatus 10 under the control of the control unit 100.

In such a plasma processing apparatus 10, the raw material gas from the gas source 44a is supplied into the processing space P and the raw material gas is converted into a plasma state by the plasma which is supplied from the plasma generating space E to the processing space P. Therefore, the silicon in the activated raw material gas reacts with the surface of the processing target substrate W to form a polycrystalline silicon film. In the plasma processing apparatus 10, the plasma is excited by the microwaves so that an electron temperature of the plasma is low. Therefore, the plasma processing apparatus 10 may grow the polycrystalline silicon layer while reducing the growth inhibition caused by high ion energy. Further, in the plasma processing apparatus 10, the polycrystalline silicon layer is grown at the low temperature so that a polycrystalline silicon layer having a reduced crystal size may be grown. As described above, when the crystal size of the polycrystalline silicon layer is made to be fine, a grain boundary becomes a mesh type. Diffusion of the dopant may be suppressed in the polycrystalline silicon layer having such a mesh type complicated grain boundary.

Further, the plasma processing apparatus 10 may supply the first gas from the gas source 45a or the second gas from the gas source 46a into the processing space P, in addition to the raw material gas from the gas source 44a. As described above, the plasma processing apparatus 10 excites the plasma having a low electron temperature so that the polycrystalline silicon layer may be grown in a state where dopant atoms are incorporated in the crystal structure of the polycrystalline silicon. Therefore, the plasma processing apparatus 10 may grow a first conductive type polycrystalline silicon layer and a second conductive type polycrystalline silicon layer which are activated. In the meantime, the gas may be adjusted to be supplied from the gas sources 44a, 45a, and 46a by controlling the valves 44b, 45b, and 46b and the flow rate controllers 44c, 45c, and 46c by the control unit 100.

Further, the plasma processing apparatus 10 may supply the dilution gas from the gas sources 47a and 48a into the processing space P, in addition to the raw material gas from the gas source 44a. In an exemplary embodiment, the dilution gas may be hydrogen gas or a mixture gas of the hydrogen gas and inert gas, for example, Ar gas. As described above, the crystallization rate of the polycrystalline silicon layer may be further increased by supplying the hydrogen gas into the processing space P, in addition to the raw material gas. In the meantime, the supply of the gas from the gas source 47a may be adjusted by controlling the valve 47b and the flow rate controller 47c by the control unit 100. Furthermore, the supply of the gas from the gas source 48a may be adjusted by controlling the valve 48b and the flow rate controller 48c by the control unit 100.

Further, the plasma processing apparatus 10 may control electrode applied from the high frequency power supply 25 to the high frequency electrode, that is, the table 14a as a bias power in a range of 100 W to 500 W, under the control of the control unit 100. The ions are drawn into the processing target substrate W by the high frequency bias power having the above-mentioned range so that the crystal size of the polycrystalline silicon layer may be further reduced.

Further, the plasma processing apparatus 10 may control the pressure adjusting unit 22 by the control unit 100, to set the pressure within the processing container 12 to be 12 Pa or less. When the pressure within the processing container 12 is adjusted to be in the above-mentioned range, the crystallization rate of the i-type polycrystalline silicon layer may be further increased.

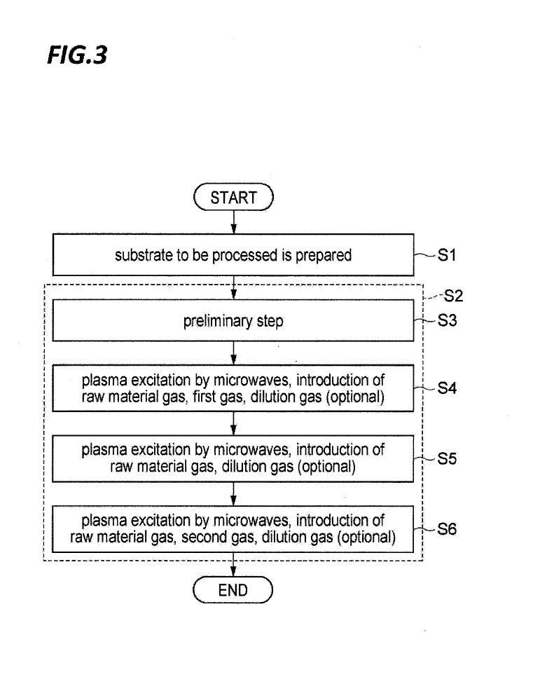

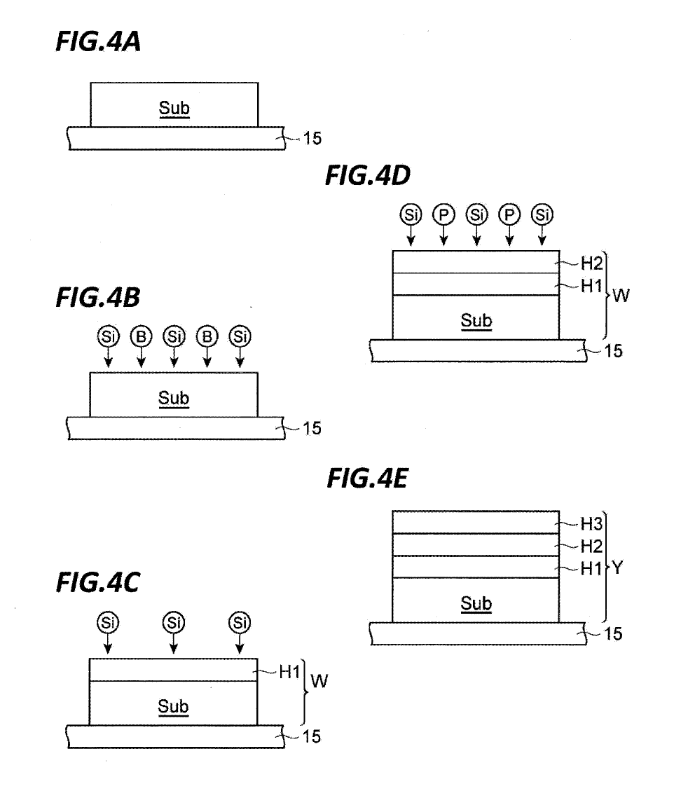

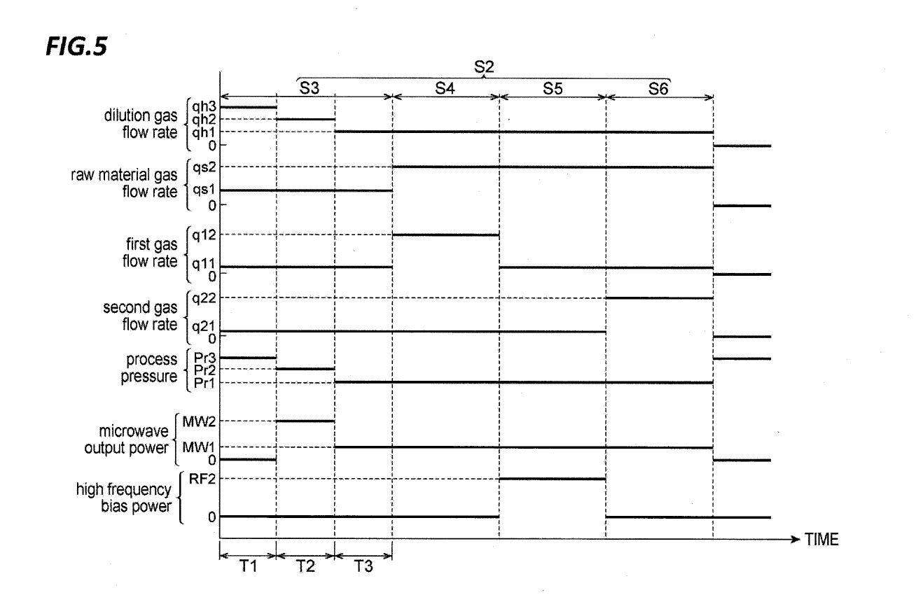

Hereinafter, an exemplary embodiment of a plasma processing method using the plasma processing apparatus 10 of FIG. 1 will be described. FIG. 3 is a flow chart illustrating a plasma processing method according to an exemplary embodiment. FIG. 4 is a view schematically illustrating a principle of forming a film in a plasma processing method according to an exemplary embodiment. FIG. 5 is a timing chart illustrating respective processes of a plasma processing method according to an exemplary embodiment.

In a plasma processing method illustrated in FIG. 3, first, as illustrated in FIG. 4A, a semiconductor substrate (denoted as “Sub” in the drawing) which is a processing target substrate W is prepared in step S1. Specifically, in step S1, the semiconductor substrate Sub is accommodated in the processing container 12, is placed on the stage 14 and is attracted by the electrostatic chuck 15.

Next, in an exemplary embodiment, a film forming process is performed in step S2. The film forming process includes a preliminary step which is a part of the film forming process and a step of growing the polycrystalline silicon layer. In step S3, the preliminary step which is a part of the film forming process is performed. Specifically, as illustrated in FIG. 5, in step S3, during a period T1, the dilution gas is supplied from the gas sources 47a and 48a into the processing space P at a flow rate qh3 while exhausting the inside of the processing container 12 by the exhausting device 23 so as to set the pressure within the processing container 12 to a predetermined pressure Pr3. Further, during the period T1, a power is applied to the heater 29 to start heating the stage 14. Further, during the period T1, the gas for generating plasma, for example, Ar gas is introduced into the plasma generating space E from the gas source 41a.

Subsequently, during a period T2, the dilution gas is supplied from the gas sources 47a and 48a into the processing space P at a flow rate qh2 which is lower than the flow rate qh3 while exhausting the inside of the processing container 12 by the exhausting device 23 so that the pressure within the processing container 12 is lowered to a pressure Pr2 which is lower than the pressure Pr3. Further, during the period T2, the gas for generating plasma is introduced from the gas source 41a into the plasma generating space E and microwaves having an output power MW2 are generated by the microwave generator 16. Then, the microwaves for plasma excitation are introduced into the plasma generating space E. Therefore, the plasma is ignited in the plasma generating space E.

Next, during a period T3, the dilution gas is supplied from the gas sources 47a and 48a into the processing space P at a flow rate qh1 which is lower than the flow rate qh2 while exhausting the inside of the processing container 12 by the exhausting device 23 so that the pressure within the processing container 12 is lowered to a pressure Pr1 which is lower than the pressure Pr2. Further, during the period T3, the gas for generating plasma is introduced from the gas source 41a into the plasma generating space E and microwaves having an output power MW1, which is lower than the output power MW2, are generated by the microwave generator 16, Then, the microwaves for plasma excitation are introduced into the plasma generating space E.

In the meantime, during the periods T1 to T3 in step S3, the flow rate of the dilution gas, the flow rate of the raw material gas, the flow rate of the first gas, or the flow rate of the second gas, and the pressure within the processing container 12 may be set as described in the following steps S4, S5, and S6. Further, during the periods T2 and T3, the output power of the microwaves generated by the microwave generator 16 may be set as described in the following steps S4, S5, and S6.

In the present plasma processing method, after the preliminary step is completed in step S3, the polycrystalline silicon layer is formed. In an exemplary embodiment, a step of forming the polycrystalline silicon layer includes step S4 of growing a p-type polycrystalline silicon layer which is a first conductive type polycrystalline silicon layer, step S5 of growing an i-type polycrystalline silicon layer, and step S6 of growing an n-type polycrystalline silicon layer which is a second conductive type polycrystalline silicon layer.

In step S4, the dilution gas is supplied from the gas sources 47a and 48a into the processing space P at a flow rate qh1, the raw material gas from the gas source 44a is supplied into the processing space P at a flow rate qs2, and the first gas from the gas source 45a is supplied into the processing space P at a flow rate ql2 while exhausting the inside of the processing container 12 by the exhausting device 23 so that a pressure within the processing container 12 is maintained at the pressure Pr1. The flow rate of the raw material gas ranges, for example, from 1 sccm to 100 sccm and the flow rate of the first gas ranges from 0.02 sccm to 2 sccm. Further, in step S4, the gas for generating plasma is introduced from the gas source 41a into the plasma generating space E to maintain the output power of the microwaves generated by the microwave generator 16 at the output power MW1. The microwave output power in step S4 ranges, for example, from 2000 W to 4000 W. Further, in an exemplary embodiment, in step S4, the dilution gas which is supplied into the processing space P may be hydrogen gas or mixture gas of the hydrogen gas and inert gas, for example, Ar gas. Further, in an exemplary embodiment, in step S4, the bias power may be applied from the high frequency power supply 25 to the high frequency electrode and the bias power may be a power in the range of 100 W to 500 W.

In step S4, the plasma is excited in the plasma generating space E and is supplied into the processing space P so that the raw material gas and the first gas are activated in the processing space P. Accordingly, as illustrated in FIG. 4B, active species (“Si” enclosed by a circle in the drawing) of silicon and active species (“B” enclosed by a circle in the drawing) of a first dopant material react with a surface of the semiconductor substrate Sub to grow a p-type polycrystalline silicon layer H1 on the semiconductor substrate Sub.

Subsequently, in step S5, the supplying of the first gas from the gas source 45a is stopped and the dilution gas is supplied from the gas sources 47a and 48a into the processing space P at a flow rate qh1 and the raw material gas from the gas source 44a is supplied into the processing space P at a flow rate qs2 while exhausting the inside of the processing container 12 by the exhausting device 23 so that the pressure within the processing container 12 is maintained at the pressure Pr1. The flow rate of the raw material gas ranges, for example, from 1 sccm to 100 sccm. Further, in step S5, the gas for generating plasma is introduced from the gas source 41a into the plasma generating space E to maintain the output power of the microwaves generated by the microwave generator 16 at the output power MW1. The microwave output power in step S5 ranges, for example, from 2000 W to 4000 W. Further, in step S5, a high frequency bias power RF2 is applied from the high frequency power supply 25 to the high frequency electrode. The high frequency bias power in step S5 ranges, for example, from 100 W to 500 W. Further, in an exemplary embodiment, in step S5, the dilution gas which is supplied into the processing space P may be hydrogen gas or mixture gas of the hydrogen gas and inert gas, for example, Ar gas.

In step S5, the plasma is excited in the plasma generating space E and is supplied into the processing space P so that the raw material gas is activated in the processing space P. Further, ions with an ion energy controlled by the high frequency bias power applied to the high frequency electrode are drawn into the surface of the processing target substrate W. Accordingly, as illustrated in FIG. 4C, active species (“Si” enclosed by a circle in the drawing) of silicon react with a surface of the processing target substrate W, that is, a surface of the p-type polycrystalline silicon layer H1 to grow an i-type polycrystalline silicon layer H2 on the p-type polycrystalline silicon layer H1.

Subsequently, in step S6, the dilution gas is supplied from the gas sources 47a and 48a into the processing space P at the flow rate qh1, the raw material gas from the gas source 44a is supplied into the processing space P at a flow rate qs2, and the second gas from the gas source 46a is supplied into the processing space P at the flow rate q22 while exhausting the inside of the processing container 12 by the exhausting device 23 so that a pressure within the processing container 12 is maintained at a pressure Pr1. The flow rate of the raw material gas ranges, for example, from 1 sccm to 100 sccm and the flow rate of the second gas ranges from 0.02 sccm to 2 sccm. Further, in step S6, the gas for generating plasma is introduced from the gas source 41a into the plasma generating space E to maintain the output power of the microwaves generated by the microwave generator 16 at the output power MW1. The microwave output power in step S6 ranges, for example, from 2000 W to 4000 W. Further, in an exemplary embodiment, in step S6, the dilution gas which is supplied into the processing space P is hydrogen gas. Alternatively, the dilution gas may be mixture gas of the hydrogen gas and the inert gas. The inert gas is, for example, Ar, He, Kr, and Xe and the dilution gas may be mixture gas of the hydrogen gas and Ar gas. For example, the dilution gas may be mixture gas with Ar gas. Further, in an exemplary embodiment, in step S6, the bias power may be applied from the high frequency power supply 25 to the high frequency electrode and the bias power may be a power in the range of 100 W to 500 W.

In step S6, the plasma is excited in the plasma generating space E and is supplied into the processing space P so that the raw material gas and the second gas are activated in the processing space P. Accordingly, as illustrated in FIG. 4D, active species (“Si” enclosed by a circle in the drawing) of silicon and active species (“P” enclosed by a circle in the drawing) of a second dopant material react with a surface of the processing target substrate W, that is, a surface of the i-type polycrystalline silicon layer H2 to grow an n-type polycrystalline silicon layer H3 on the i-type polycrystalline silicon layer H2.

After the above steps S1 to S6 are completed, as illustrated in FIG. 4E, a semiconductor apparatus Y in which the p-type polycrystalline silicon layer H1, the i-type polycrystalline silicon layer H2, and the n-type polycrystalline silicon layer H3 are laminated on the semiconductor substrate Sub is formed.

In the plasma processing method, the plasma having a low electron temperature is excited by the microwaves and silicon contained in the raw material gas is activated by the plasma. Therefore, the growth inhibition due to the high ion energy is reduced so that the polycrystalline silicon layers H1 to H3 are grown. Further, the crystal growth is possible at a low temperature so that the i-type polycrystalline silicon layer H2 having a reduced crystal size may be grown. As a result, the dopant is suppressed from being diffused onto the i-type polycrystalline silicon layer H2.

Further, in an exemplary embodiment, in addition to the raw material gas, the first gas and the second gas are introduced into the processing space P to grow the p-type polycrystalline silicon layer H1 and the n-type polycrystalline silicon layer H3. When the p-type polycrystalline silicon layer H1 and the n-type polycrystalline silicon layer H3 are grown, the plasma having a low electron temperature is excited so that the polycrystalline silicon layer may be grown in a state where the dopant atoms are incorporated in a crystal structure of the polycrystalline silicon. Therefore, the p-type polycrystalline silicon layer H1 and the n-type polycrystalline silicon layer H3 may be grown in a state where they are activated. That is, the p-type polycrystalline silicon layer H1 and the n-type polycrystalline silicon layer H3 may be grown in a state where they are activated, without performing an annealing process for activating the dopant, and as a result, increase of a crystal size due to the annealing process may be suppressed.

Further, in an exemplary embodiment, as described above, in steps S4 to S6, the dilution gas containing hydrogen may be introduced into the processing space P. As described above, the hydrogen gas is used as the dilution gas so that the crystallization rates of the polycrystalline silicon layers H1 to H3 may be improved.

Further, in an exemplary embodiment, in step S4 to S6, the high frequency bias power may be applied to the high frequency electrode. Therefore, the energy of the ions drawn into the processing target substrate W is controlled and thus, the crystal sizes of the polycrystalline silicon layers H1 to H3 may be controlled. In an exemplary embodiment, the high frequency bias power may range from 100 W to 500 W. By the high frequency base power in the above-mentioned range, the crystallization rates of the polycrystalline silicon layers H1 to H3 may be further increased and the crystal sizes of the polycrystalline silicon layers H1 to H3 may be further reduced.

Further, in an exemplary embodiment, in the steps S4 to S6 of growing the polycrystalline silicon layers H1 to H3, the pressure within the processing container 12 may be set to be 12 Pa or less. The pressure within the processing container 12 is set to be in the above-mentioned range, so that the crystallization rates of the polycrystalline silicon layers H1 to H3 may be further increased.

Even though several exemplary embodiments have been described, the present disclosure is not limited to the above-described exemplary embodiment but various modified aspects may be configured. For example, the first conductive type polycrystalline silicon layer may be an n-type semiconductor layer or the second conductive type polycrystalline silicon layer may be a p-type semiconductor layer.

Hereinafter, Test Examples which are performed using the plasma processing apparatus 10 will be described.

### Test Example 1

In Test Example 1, the i-type polycrystalline silicon layer was grown on the semiconductor substrate while considering a high frequency bias power of 13.65 MHz as a variable parameter. Conditions in Test Example 1 are as follows.

Flow rate of raw material gas: 5 sccm

Flow rate of dilution gas (H₂ gas): 395 sccm

Output power of microwave: 4000 W

Frequency of microwave: 2.45 GHz

Flow rate of gas (Ar gas) for generating plasma: 0 sccm

Pressure within processing container 12: 4 Pa

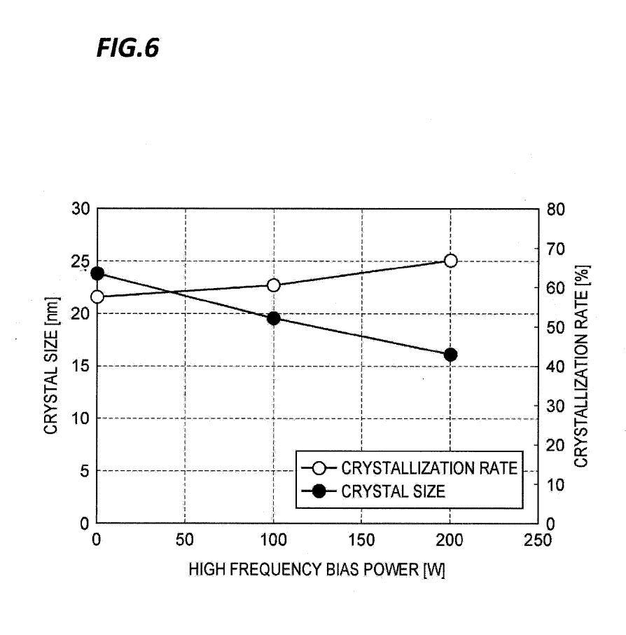

In Test Example 1, the i-type polycrystalline silicon layer which was grown with the high frequency bias power as a variable parameter was analyzed by an X-ray diffraction method (XRD), the crystal size of the i-type polycrystalline silicon layer was obtained by a Scherrer method, and the crystallization rate was obtained by Raman spectroscopy. A result of Test Example 1 is illustrated in FIG. 6. In FIG. 6, a plot colored with black represents a crystal size and a white plot represents a crystallization rate. As is obvious from FIG. 6, by Test Example 1, it is confirmed that as the high frequency bias power is increased, the crystal size of the polycrystalline silicon layer may be reduced. It is confirmed that a polycrystalline silicon layer having a reduced crystal size which is 20 nm or less may be obtained by the high frequency bias power of 100 W or higher. It is also known that the crystallization rate is increased until the high frequency bias power is 200 W.

### Test Example 2

In Test Example 2, a variable range of a high frequency bias power of 13.65 MHz was further broadened to grow the i-type polycrystalline silicon layer on the semiconductor substrate. Conditions in Test Example 2 are as follows.

Flow rate of raw material gas: 15 sccm

Flow rate of dilution gas (H₂ gas): 400 sccm

Output power of microwave: 4000 W

Frequency of microwave: 2.45 GHz

Flow rate of gas (Ar gas) for generating plasma: 0 sccm

Pressure within processing container 12: 4 Pa

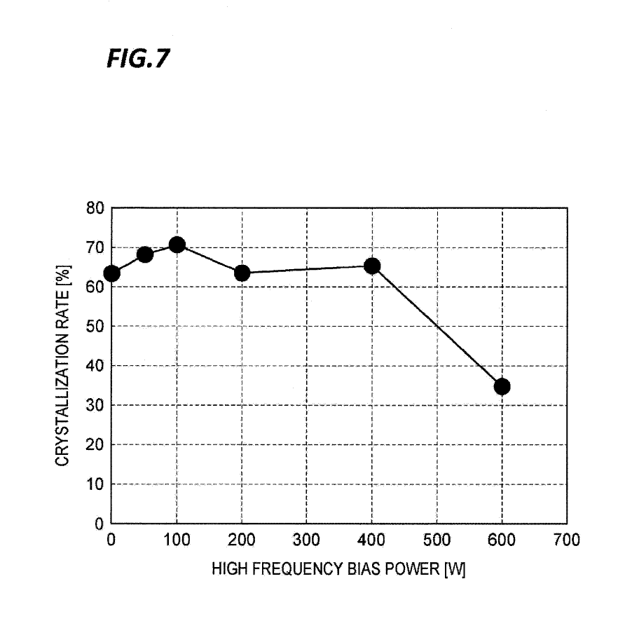

In Test Example 2, the i-type polycrystalline silicon layer which is grown with the high frequency bias power as a variable parameter was analyzed by an X-ray diffraction method (XRD) and the crystallization rate was obtained by Raman spectroscopy. A result of Test Example 2 is illustrated in FIG. 7. As is obvious from FIG. 7, by Test Example 2, it is confirmed that when the high frequency bias power exceeds 400 W, the crystallization rate is lowered as the high frequency bias power is increased. Further, it is confirmed that in order to obtain a polycrystalline silicon layer having a crystallization rate of 40% or higher, the hydrogen gas is used as for the dilution gas and the high frequency bias power is set to be 500 W or lower. As a result, it is confirmed that when the hydrogen gas is used as for the dilution gas and the high frequency bias power is set to be in a range of 100 W to 500 W, a polycrystalline silicon layer having a more reduced crystal size and a higher crystallization rate may be obtained.

### Test Example 3

In Test Example 3, the i-type polycrystalline silicon layer was grown on the semiconductor substrate while considering a pressure within the processing container 12 as a variable parameter. Conditions in Test Example 3 are as follows.

Flow rate of raw material gas: 5 sccm

Flow rate of dilution gas (H₂ gas): 395 sccm

Output power of microwave: 4000 W

Frequency of microwave 2.45 GHz

High frequency bias power: 0 W

Frequency of high frequency bias: 13.65 MHz

Flow rate of gas (Ar gas) for generating plasma: 0 sccm

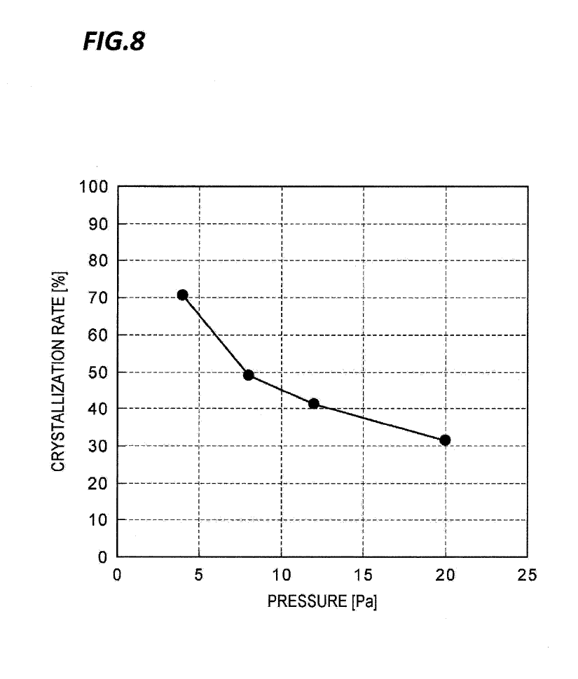

In Test Example 3, the i-type polycrystalline silicon layer which is grown with the pressure within the processing container 12 as a variable parameter was analyzed by an X-ray diffraction method (XRD) and the crystallization rate was obtained by Raman spectroscopy. A result of Test Example 3 is illustrated in FIG. 8. As is obvious from FIG. 8, it is confirmed that the crystallization rate of 40% or higher may be achieved by the pressure within the processing container 12 which is 12 Pa or less.

### Test Example 4

In Test Example 4, the p-type polycrystalline silicon layer, the i-type polycrystalline silicon layer, and the n-type polycrystalline silicon layer were grown on the semiconductor substrate. In Test Example 4, the p-type polycrystalline silicon layer was grown on the processing target substrate W while considering the output power of the microwaves of 2.45 GHz, a temperature of the stage 14 on which the processing target substrate W is placed, and the pressure of the processing space P as variable parameters. Conditions for growing the p-type polycrystalline silicon layer in Test Example 4 are as follows.

Flow rate of raw material gas: 5 sccm

Flow rate of dilution gas (H₂ gas): 394.91 sccm

Flow rate of first gas: 0.09 sccm

Frequency of microwave: 2.45 GHz

High frequency bias power: 0 W

Flow rate of gas (Ar gas) for generating plasma: 0 sccm

When the p-type polycrystalline silicon layer was grown while considering the output power of the microwaves as a variable parameter, a temperature of the stage 14 was set as 400° C. and the pressure in the processing container 12 was set as 4 Pa. Further, when the p-type polycrystalline silicon layer was grown while considering the temperature of the stage 14 as a variable parameter, the output power of the microwaves was set as 4000 W and the pressure within the processing container 12 was set as 4 Pa. Further, when the pressure within the processing container 12 was considered as a variable parameter, the output power of the microwaves was set as 4000 W and the temperature of the stage 14 was set as 400° C.

In the meantime, conditions for growing the i-type polycrystalline silicon layer in Test Example 4 are as follows.

Flow rate of raw material gas: 15 sccm

Flow rate of dilution gas (H₂ gas): 400 sccm

Output power of microwave: 4000 W

Frequency of microwave: 2.45 GHz

High frequency bias power: 200 W

Frequency of High frequency bias: 13.65 MHz

Flow rate of gas (Ar gas) for generating plasma: 0 sccm

Temperature of stage: 400° C.

Pressure within processing container: 4 Pa

Further, conditions for growing the n-type polycrystalline silicon layer in Test Example 4 are as follows.

Flow rate of raw material gas: 5 sccm

Flow rate of dilution gas (H₂ gas): 393.5 sccm

Flow rate of second gas: 1.5 sccm

Output power of microwave: 4000 W

Frequency of microwave: 2.45 GHz

High frequency bias power: 0 W

Flow rate of gas (Ar gas) for generating plasma: 0 sccm

Temperature of stage: 400° C.

Pressure within processing container: 4 Pa

In Test Example 4, it was evaluated whether boron (B) which is a dopant on the p-type polycrystalline silicon layer was activated, by using resistivity. In Test Example 4, when the resistivity of the p-type polycrystalline silicon layer was 1.0 Ω·cm or lower, it was determined that the dopant was activated.

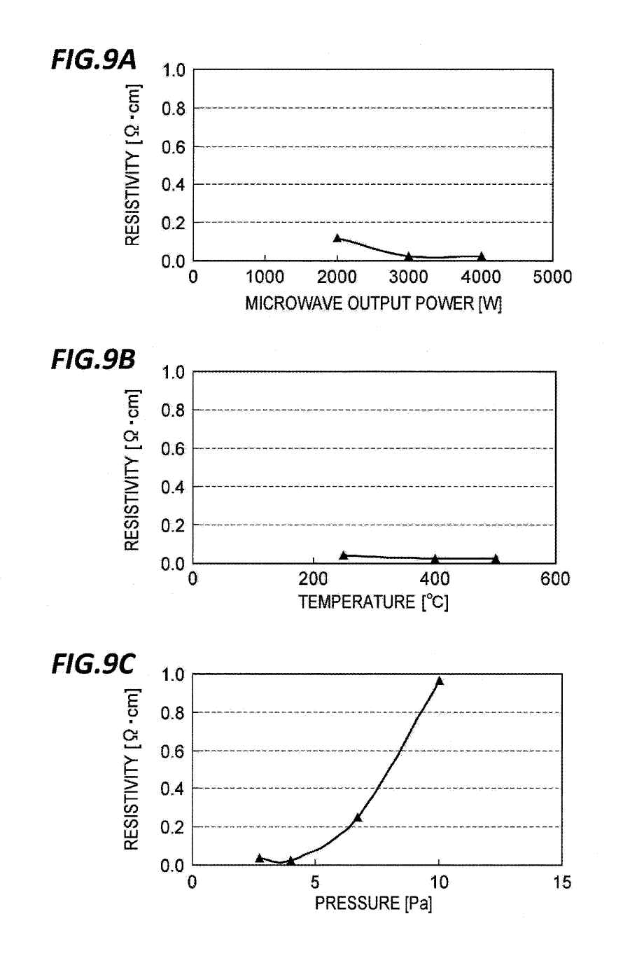

First, it was evaluated whether a dopant of the p-type polycrystalline silicon layer which was grown with the output power of the microwaves as a variable parameter was activated. The evaluation result is illustrated in FIG. 9A. As is obvious from FIG. 9A, it was confirmed that when the output power of the microwaves is in the range of 2000 W to 4000 W, the resistivity is 0.2 Ω·cm or less. As a result, it was confirmed that when the output power of the microwaves is in the range of 2000 W to 4000 W, the activated p-type polycrystalline silicon layer may be grown. In the meantime, even if the output power of the microwaves was varied in the range of 2000 W to 4000 W, the resistivity was comparatively slightly changed. Therefore, it was confirmed that dependency of the resistivity of the p-type polycrystalline silicon layer on the output power of the microwaves is small.

Next, it was evaluated whether the dopant of the p-type polycrystalline silicon layer which was grown with the temperature of the stage 14 as a variable parameter was activated, using the resistivity of the p-type polycrystalline silicon layer. The evaluation result is illustrated in FIG. 9B. As is obvious from FIG. 9B, it was confirmed that when the temperature of the stage 14 is in the range of 250° C. to 500° C., the resistivity is 0.1 Ω·cm or less. As a result, it was confirmed that when the temperature of the stage 14 is in the range of 250° C. to 500° C., the activated p-type polycrystalline silicon layer may be grown. In the meantime, when the temperature of the stage 14 was varied in the range of 250° C. to 500° C., the resistivity is comparatively slightly changed. Therefore, it was confirmed that dependency of the resistivity of the p-type polycrystalline silicon layer on the temperature of the stage 14 is small.

Next, it was evaluated whether the dopant of the p-type polycrystalline silicon layer which was grown with the pressure within the processing container 12 as a variable parameter was activated, using the resistivity of the p-type polycrystalline silicon layer. The evaluation result is illustrated in FIG. 9C. As is obvious from FIG. 9C, it was confirmed that when the pressure within the processing container 12 is 12 Pa or less, the resistivity is 0.1 Ω·cm or less. As a result, it was confirmed that when the pressure within the processing container 12 is 12 Pa or less, the activated p-type polycrystalline silicon layer may be grown. Further, it was confirmed that as the pressure within the processing container 12 is increased, the resistivity of the p-type polycrystalline silicon layer is increased. When the pressure within the processing container 12 is higher than 12 Pa, a plasma density is lowered. Thus, it is considered that the dopant is not activated in a state immediately after the p-type polycrystalline silicon layer is grown.

### Test Example 5

In Test example 5, the p-type polycrystalline silicon layer, the i-type polycrystalline silicon layer, and the n-type polycrystalline silicon layer were grown on the semiconductor substrate using a plasma CVD device which includes a radial line slot antenna (RLSA). Conditions for growing the polycrystalline silicon layers in Test Example 5 are as follows.

[Conditions for Growing p-Type Polycrystalline Silicon Layer]

Flow rate of raw material gas: 5 sccm

Flow rate of dilution gas (H₂ gas): 394.91 sccm

First gas: 0.09 sccm

Output power of microwave: 4000 W

Frequency of microwave 2.45 GHz

High frequency bias power: 0 W

Flow rate of gas (Ar gas) for generating plasma: 0 sccm

Temperature of stage: 400° C.

Pressure within processing container: 4 Pa

[Conditions for Growing i-Type Polycrystalline Silicon Layer]

Flow rate of raw material gas: 15 sccm

Flow rate of dilution gas (H₂ gas): 400 sccm

Output power of microwave: 4000 W

Frequency of microwave: 2.45 GHz

High frequency bias power: 200 W

Frequency of High frequency bias: 13.65 MHz

Flow rate of gas (Ar gas) for generating plasma: 0 sccm

Temperature of stage: 400° C.

Pressure within processing container: 4 Pa

[Conditions for Growing n-Type Polycrystalline Silicon Layer]

Flow rate of raw material gas: 5 sccm

Flow rate of dilution gas (H₂ gas): 393.5 sccm

Flow rate of second gas: 1.5 sccm

Output power of microwave: 4000 W

Frequency of microwave: 2.45 GHz

High frequency bias power: 0 W

Flow rate of gas (Ar gas) for generating plasma: 0 sccm

Temperature of stage: 400° C.

Pressure within processing container: 4 Pa

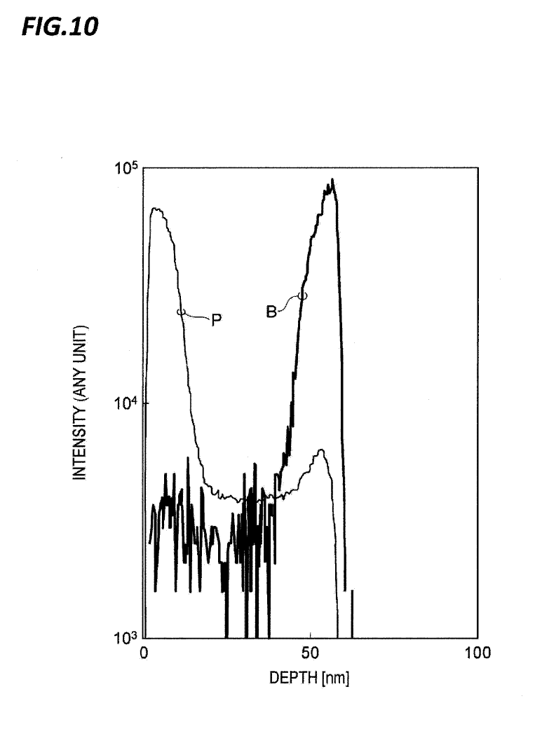

In Test Example 5, distribution of dopants was analyzed in the p-type polycrystalline silicon layer, the i-type polycrystalline silicon layer, and the n-type polycrystalline silicon layer which were grown in accordance with the above-described conditions. In Test Example 5, distribution of phosphorus (P) and distribution of boron (B) in the p-type polycrystalline silicon layer, the i-type polycrystalline silicon layer, and the n-type polycrystalline silicon layer were analyzed using a time of flight secondary ion mass spectrometry (TOF-SIMS). A result of Test Example 5 is illustrated in FIG. 10. In FIG. 10, distributions of phosphorus and boron are represented by an intensity obtained by detecting secondary ions generated by colliding ions onto the surfaces of the polycrystalline silicon layers, using a mass spectrometry. Further, a depth in FIG. 10 is defined to be increased in a direction from the n-type polycrystalline silicon layer to the p-type polycrystalline silicon layer. Further, in FIG. 10, the plot represented with the bold line represents the distribution of boron and a plot represented with the thin line represents the distribution of phosphorus. As is obvious from FIG. 10, it is confirmed that distribution of boron is sharply changed in the vicinity of a boundary between the p-type polycrystalline silicon layer and the i-type polycrystalline silicon layer. Further, it is confirmed that distribution of phosphorus is sharply changed in the vicinity of a boundary between the n-type polycrystalline silicon layer and the i-type polycrystalline silicon layer. As a result, it is confirmed that the diffusion of phosphorous, which is a dopant of the p-type polycrystalline silicon layer, onto the i-type polycrystalline silicon layer is suppressed. Further, it is confirmed that the diffusion of boron, which is a dopant of the n-type polycrystalline silicon layer, onto the i-type polycrystalline silicon layer is suppressed.

### DESCRIPTION OF SYMBOLS

10: Plasma processing apparatus, 12: Processing container, 14: Stage (mounting stage), 16: Microwave generator, 22: Pressure adjusting unit, 25: High frequency power supply, 41, 43: Gas introducing unit, 42: Shower plate, 100: Control unit, E: Plasma generating space, P: Processing space, H1: p-type polycrystalline silicon layer (first conductive type polycrystalline silicon layer), H2: i-type polycrystalline silicon layer, H3: n-type polycrystalline silicon layer (second conductive type polycrystalline silicon layer), W: Processing target substrate

1. A plasma processing method for growing a polycrystalline silicon layer on a substrate to be processed (“processing target substrate”), the method comprising:
preparing a processing target substrate in a processing container; and
growing the polycrystalline silicon layer on the processing target substrate by introducing microwaves for plasma excitation into the processing container and a silicon-containing raw material gas into the processing container.

2. The plasma processing method of claim 1, wherein the growing of the polycrystalline silicon layer includes:
growing a first conductive type polycrystalline silicon layer on the processing target substrate by introducing the raw material gas and a first gas containing a first dopant material into the processing container;
growing an i-type polycrystalline silicon layer on the first conductive type polycrystalline silicon layer by introducing the raw material gas into the processing container; and
growing a second conductive type polycrystalline silicon layer on the i-type polycrystalline silicon layer by introducing the raw material gas and a second gas containing a second dopant material into the processing container.

3. The method of claim 2, wherein in the growing of the i-type polycrystalline silicon layer, a dilution gas containing hydrogen is introduced into the processing container.

4. The method of claim 3, wherein in the growing of the i-type polycrystalline silicon layer, a high frequency bias power is applied to a mounting stage on which the processing target substrate is placed, the mounting stage constituting an electrode.

5. The method of claim 4, wherein the high frequency bias power ranges from 100 W to 500 W.

6. The method of claim 1, wherein in the growing of the polycrystalline silicon layer, a pressure within the processing container is set to be 12 Pa or less.

7. A plasma processing apparatus, comprising:
a processing container configured to accommodate a processing target substrate therein;
a microwave generator configured to generate microwaves;
an antenna connected to the microwave generator to radiate microwaves for plasma excitation into the processing container; and
a gas introducing unit configured to introduce a silicon-containing raw material gas into the processing container.

8. The plasma processing apparatus of claim 7, further comprising:
a control unit configured to control the gas introducing unit and the microwave generator,
wherein the gas introducing unit introduces a first gas containing a first dopant material and a second gas containing a second dopant material into the processing container, and
the control unit causes the gas introducing unit to introduce the raw material gas and the first gas into the processing container to grow a first conductive type polycrystalline silicon layer on the processing target substrate, to introduce the raw material gas into the processing container to grow an i-type polycrystalline silicon layer on the first conductive type polycrystalline silicon layer, and to introduce the raw material gas and the second gas into the processing container to grow a second conductive type polycrystalline silicon layer on the i-type polycrystalline silicon layer.

9. The plasma processing apparatus of claim 8, wherein the gas introducing unit further introduces a dilution gas containing hydrogen into the processing container, and
the control unit causes the gas introducing unit to introduce the dilution gas into the processing container when the i-type polycrystalline silicon layer is grown.

10. The plasma processing apparatus of claim 9, further comprising:
a mounting stage on which the processing target substrate is placed, the mounting stage being provided in the processing container and constituting an electrode; and
a high frequency power supply connected to the mounting stage and configured to generate a high frequency bias power to be applied to the electrode.

11. The plasma processing apparatus of claim 10, wherein when the i-type polycrystalline silicon layer is grown, the control unit causes the high frequency power supply to generate a high frequency bias power ranging from 100 W to 500 W.

12. The plasma processing apparatus of claim 8, further comprising:
a pressure adjusting unit configured to adjust a pressure within the processing container,
wherein the control unit causes the pressure adjusting unit to set the pressure within the processing container to be 12 Pa or less.
